(19) United States
(12) Patent Application Publication
(10) Pub. No.: US 2025/0112214 A1
(43) Pub. Date: Apr. 3, 2025

(54) METHOD FOR PRODUCING A CIRCUIT ARRANGEMENT FOR AN ELECTRIC MACHINE, POWER SEMICONDUCTOR MODULE FOR A CIRCUIT ARRANGEMENT, AND CORRESPONDING CIRCUIT ARRANGEMENT

(71) Applicant: AUDI AG, Ingolstadt (DE)

(72) Inventor: Daniel RUPPERT, Lenting (DE)

(21) Appl. No.: 18/890,473

(22) Filed: Sep. 19, 2024

(30) Foreign Application Priority Data
Sep. 28, 2023 (DE) 102023126438.9

(51) Int. Cl. H01L 25/16; H01L 23/00; H01L 23/367

(52) U.S. Cl. CPC H01L 25/16; H01L 24/16; H01L 24/40; H01L 24/73; H01L 24/81; H01L 24/84; H01L 24/92; H01L 23/3675; H01L 2224/16145; H01L 2224/40195; H01L 2224/73205; H01L 2224/81191; H01L 2224/84801; H01L 2224/92153

(57) ABSTRACT

A method for producing a circuit arrangement for an electric machine is provided. The circuit arrangement has at least one power input which is connectable to an electric energy storage device, at least one power semiconductor which is arranged in a power semiconductor module, and at least one power output which is connectable to an excitation coil of the electric machine, wherein the power input is electrically connected to a first power terminal of the power semiconductor module via an intermediate circuit of the circuit arrangement, and the power output is electrically connected to a second power terminal of the power semiconductor module via a control board of the circuit arrangement. A power semiconductor module for a circuit arrangement for an electric machine, and to a corresponding circuit arrangement is also provided.

### BACKGROUND

### Technical Field

The present disclosure relates to a method for producing a circuit arrangement for an electric machine, wherein the circuit arrangement has at least one power input which is connectable to an electric energy storage device, at least one power semiconductor arranged in a power semiconductor module, and at least one power output which is connectable to an excitation coil of the electric machine, wherein the power input is electrically connected to a first power terminal of the power semiconductor module via an intermediate circuit of the circuit arrangement, and the power output is electrically connected to a second power terminal of the power semiconductor module via a control board of the circuit arrangement, wherein the second power terminal is formed as at least one contact pin that protrudes beyond the power semiconductor module and is pressed into a contact recess in the control board. The present disclosure further relates to a power semiconductor module for a circuit arrangement for an electric machine, and a corresponding circuit arrangement.

### Description of the Related Art

For example, publication DE 10 2019 132 685 A1 is known from the prior art. It relates to an electrical circuit arrangement including an excitation circuit and an inverter circuit, wherein the inverter circuit is arranged on a first support element and includes an intermediate circuit capacitor arranged on a direct current side of the inverter circuit, wherein the intermediate circuit capacitor has at least one terminal, wherein the excitation circuit is arranged on a second support element, wherein the excitation circuit is connected to the intermediate circuit capacitor via a direct connection of the second support element to at least one terminal of the intermediate circuit capacitor.

### BRIEF SUMMARY

Embodiments of the present disclosure provide a method for producing a circuit arrangement which has advantages over the prior art, such as enabling a more reliable and more efficient connection of the power semiconductor module to the intermediate circuit.

The present disclosure described herein provides a method for producing a circuit arrangement for an electric machine. For this purpose, it is provided that the first power terminal on the power semiconductor module is formed to be planar and is electrically and mechanically connected to a busbar of an intermediate circuit capacitor of the intermediate circuit.

The circuit arrangement serves to provide an excitation voltage for the excitation coil of the electric machine. The electric machine may be part of a drive device of a motor vehicle and serves to provide a drive torque aimed at driving the motor vehicle. For this purpose, electric energy is converted into mechanical energy at least temporarily by the electric machine. In this case, the electric energy is taken, for example, from an electric energy storage device, which can also be referred to as a traction battery. In some embodiments, the electric machine may be electrically connectable or electrically connected to the energy storage device via the circuit arrangement.

To provide the drive torque, the electric machine generates a rotating field at least temporarily. This is done by at least one inverter, which is electrically connected to the electric machine to provide an alternating voltage for a stator winding of the electric machine. In some embodiments, the inverter may be a multiphase inverter, such as a three-phase inverter. Accordingly, the electric machine is a multiphase electric machine, such as a three-phase electric machine.

In addition to the rotating field, the electric machine generates an excitation field. For this purpose, the electric machine has the excitation coil, which is, for example, formed as a corresponding rotor winding of the electric machine. During operation of the electric machine, the excitation field rotates synchronously with the rotating field. The electric machine is formed as an externally excited synchronous machine.

The excitation voltage used to generate the excitation field of the electric machine is generated from a direct voltage provided by the electric energy storage device. This is done by the circuit arrangement, which has the power input which is connectable or connected to the energy storage device, and the power output which is connectable or connected to the excitation coil. In other words, the circuit arrangement is connectable or connected to the energy storage device on the input side and connectable or connected to the excitation coil on the output side. For example, the power input of the circuit arrangement includes a first power input which is connectable or connected to a first pole of the energy storage device, and a second power input which is connectable or connected to a second pole of the energy storage device. The power output includes, for example, a first power output which is connectable or connected to a first pole of the excitation coil, and a second power output which is connectable or connected to a second pole of the excitation coil.

The circuit arrangement has the intermediate circuit on the input side. The intermediate circuit has the intermediate circuit capacitor, which is provided for smoothing the direct voltage provided at the power input. The intermediate circuit capacitor is accordingly connected in parallel to the power input. A first pole of the intermediate circuit capacitor may be electrically connected to the first power input, and a second pole of the intermediate circuit capacitor may be electrically connected to the second power input. The intermediate circuit capacitor accordingly provides an intermediate circuit voltage present at its poles.

The excitation voltage is generated from the intermediate circuit voltage present at the intermediate circuit capacitor. For this purpose, the circuit arrangement has the at least one power semiconductor which is arranged in the power semiconductor module. The power semiconductor module has the first power terminal and the second power terminal, which are electrically connected to one another via the power semiconductor which is arranged in the power semiconductor module. The first power terminal of the power semiconductor module is connected to the intermediate circuit of the circuit arrangement. In this respect, the first power terminal is electrically connected to the power input of the circuit arrangement via the intermediate circuit.

The power semiconductor module is configured to convert the intermediate circuit voltage present at the first power terminal into the excitation voltage, and to provide this excitation voltage at the second power terminal. The power semiconductor module may be formed as a DC-DC converter. For example, the power semiconductor module includes at least two transistors and at least two freewheeling diodes, which together form the DC-DC converter. The power semiconductor module may be formed as a two-quadrant chopper. The second power terminal of the power semiconductor module is electrically connected to the power output of the circuit arrangement. In this respect, the excitation voltage generated by the power semiconductor module is provided at the power output.

In addition to the power semiconductor module, in some embodiments the circuit arrangement may include the inverter already explained above, which serves to provide the alternating voltage for generating the rotating field. In this case, the inverter is also electrically connected to the intermediate circuit. In the circuit arrangement, both the excitation voltage provided for generating the excitation field, and the alternating voltage provided for generating the rotating field may be generated from the intermediate circuit voltage. This is done by the power semiconductor module or the inverter. For providing the alternating voltage, the circuit arrangement may have corresponding additional power outputs that are connected to the inverter on the output side.

The circuit arrangement also has the control board. The control board serves to control the circuit arrangement, such as to control the power semiconductor module and/or the inverter. The power semiconductor module is attached to the control board, which means that the power semiconductor module and the control board are connected to each other both mechanically and electrically. The power semiconductor module is connected to the control board at least by the second power terminal of the power semiconductor module. This terminal is formed as the at least one contact pin protruding beyond the power semiconductor module.

The control board has the contact recess into which the contact pin of the second power terminal is pressed. The contact recess of the control board is connected to the power output of the circuit arrangement via at least one conductor track of the control board. In this respect, the second power terminal is electrically connected to the power output of the circuit arrangement via the control board.

During production of the circuit arrangement, the control board and the power semiconductor module are connected to one another by pressing the contact pin into the contact recess of the control board. This simultaneously creates the electrical connection between the second power terminal and the conductor track, and the mechanical connection of the power semiconductor module to the control board. The contact recess is, for example, formed as a hole in the control board, the inner wall of which is configured to be electrically conductive and is connected to the conductor track.

The contact pin protrudes from an outer wall of the power semiconductor module. For pressing in said pin, the control board and the outer wall of the power semiconductor module are arranged parallel to one another so that a longitudinal center axis of the contact pin and a longitudinal center axis of the contact recess are aligned. The control board and the power semiconductor module are then moved towards one another using an appropriate pressing force, whereby the contact pin is pushed into the contact recess and pressed into it.

The contact pin and the contact recess are configured in such a way that the contact pin is held in the contact recess in a force-fitting or clamped manner after being pressed in. The pressing-in process connects the control board and the power semiconductor module both electrically and mechanically. It should be noted that the mechanical connection does not have to be made exclusively by the second power terminal. Rather, the power semiconductor module can have additional contact pins pressed into the control board and/or a screw connection can be provided for attaching the power semiconductor module.

It could now be provided to configure the first power terminal of the power semiconductor module also as at least one contact pin that protrudes beyond the power semiconductor module and to connect this pin to the control board by pressing it in. In this case, the electrical connection of the power semiconductor module to the intermediate circuit or the intermediate circuit capacitor would be formed via the control board. Accordingly, for example, a screw connection or other connection of the control board to the intermediate circuit capacitor would have to be provided. This not only entails higher material and production costs, but also causes or increases stray inductances on the input side, which require filtering measures in order to minimize them.

Instead, the present disclosure described herein provides that the first power terminal on the power semiconductor module is formed to be planar. This enables a connection, such as a direct connection, of the power semiconductor module to the intermediate circuit capacitor, bypassing the control board. The intermediate circuit capacitor has the busbar, which is connected to the planar first power terminal to connect the intermediate circuit. A busbar is understood to mean a planar current busbar, via which the intermediate circuit capacitor is connected to the power semiconductor module and the inverter. In other words, both the power semiconductor module and the inverter may be connected to the same busbars of the intermediate circuit capacitor.

Busbars are usually used to establish electrical connections that are designed for high current or high electrical power. Busbars are therefore used to connect to power semiconductor modules that are designed to transmit high power. In this case, corresponding planar connections are usually provided on both the input side and the output side for connection to the busbars. However, the present disclosure provides for only the first power terminal of the power semiconductor module to be formed planar for connection to a busbar, whereas the second power terminal is formed as the at least one contact pin.

The first power terminal has at least one, such as flat, contact surface that is configured to be in touching contact with the busbar of the intermediate circuit capacitor. The power semiconductor module is connected to the busbar of the intermediate circuit capacitor both electrically and mechanically by connecting the busbar to the first power terminal at the contact surface.

In some embodiments, the first power terminal may have at least two contact surfaces which are arranged at a distance from one another and which are each provided for connection to the first pole and second pole of the intermediate circuit capacitor. Accordingly, both the first pole and the second pole of the intermediate circuit capacitor are may be each formed as a busbar.

The first power terminal of the power semiconductor module is not connected to the power input of the circuit arrangement via the control board. Rather, the electrical connection of the first power terminal to the intermediate circuit capacitor takes place bypassing the control board. In some embodiments, the first power terminal of the power semiconductor module may be connected directly to the busbar of the intermediate circuit capacitor bypassing the control board.

The present disclosure is based on the finding that connecting the power semiconductor module to the intermediate circuit capacitor via the busbar has advantages over connecting it via the control board. The control board can be produced more cost-effectively. The screw connection or other connection of the control board to the intermediate circuit capacitor that is usually provided is not required or is eliminated. Furthermore, stray inductances that occur on the input side are minimized and the filtering measures required when connecting via the control board are avoided. Overall, the present disclosure creates a more efficient and more reliable circuit arrangement, such as a more efficient and more reliable connection of the power semiconductor mode to the intermediate circuit capacitor.

One embodiment of the present disclosure provides that the power semiconductor module may be attached to a heat sink of the circuit arrangement before the first power terminal is connected to the busbar of the intermediate circuit capacitor. The heat sink may be part of a frame supporting the circuit arrangement or may be attached to such a frame.

The heat sink may be configured to dissipate heat generated by the power semiconductor module. The power semiconductor module is attached to the heat sink in such a way that it abuts planarly against the heat sink. The power semiconductor module may abut against the heat sink with a side opposite the first power terminal and/or the second power terminal. For example, the first power terminal and/or the second power terminal are arranged on a top side of the power semiconductor module so that a bottom side of the power semiconductor module abuts against the heat sink. This enables particularly efficient dissipation of the heat generated by the power semiconductor module.

One embodiment of the present disclosure provides that the power semiconductor module is attached to the heat sink by surface sintering and/or surface soldering. The power semiconductor module may abut against the heat sink with its bottom side, as already mentioned above.

The bottom side may be configured to be flat. In this case, it is provided to attach the power semiconductor module to the heat sink with its bottom side. This is done by surface sintering and/or surface soldering. In particular, no screw connection is provided for attaching the power semiconductor module to the heat sink. Instead, the power semiconductor module is attached directly to the heat sink by sintering or soldering. This enables particularly reliable attachment.

In one embodiment, the present disclosure provides that the first power terminal may be electrically and mechanically connected to the busbar of the intermediate circuit capacitor by welding. The intermediate circuit capacitor is arranged adjacent to the heat sink, for example on the frame supporting the circuit arrangement. The intermediate circuit capacitor may be arranged in such a way that its busbar is in touching contact with the first power terminal after the power semiconductor module has been attached to the heat sink.

After the power semiconductor module has been attached to the heat sink, the first power terminal is connected to the busbar. For this purpose, the first power terminal is welded to the busbar, which connects the first power terminal to the busbar both electrically and mechanically. Alternatively, it is provided to connect the first power terminal and the busbar by a screw connection. After connection, the first power terminal is directly connected to the busbar. This creates a particularly reliable electrical connection between the power semiconductor module and the intermediate circuit capacitor.

In one embodiment, the present disclosure provides that the control board is connected to the power semiconductor module after the power semiconductor module has been attached to the heat sink by pressing at least one contact pin into the contact recess of the control board. The connection of the power semiconductor module to the control board by pressing in the contact pin has already been mentioned above.

In one embodiment, the power semiconductor module may be connected to the control board after the first power terminal has been connected to the busbar of the intermediate circuit capacitor. In other words, the power semiconductor module may be attached to the heat sink first. The first power terminal is then connected to the busbar. The second power terminal is then connected to the control board by pressing the contact pin into the contact recess, attaching the control board to the power semiconductor module. This ensures that the first power terminal is not covered by the control board when it is connected to the busbar.

Alternatively, it is provided to first attach the power semiconductor module to the heat sink and then the control board to the power semiconductor module. In this case, the first power terminal may be connected to the busbar when the control board is already attached. In this case, the control board may be configured in such a way that the first power terminal is not covered by the control board. For example, the control board has a corresponding recess through which the first power terminal is accessible for connection to the busbar when the control board is already attached.

The present disclosure further relates to a power semiconductor module for a circuit arrangement for an electric machine, such as for a circuit arrangement produced by the method described herein, wherein the power semiconductor module has a first power terminal and a second power terminal, which are electrically connected to one another via a power semiconductor which is arranged in the power semiconductor module, wherein the second power terminal is formed as at least one contact pin protruding beyond the power semiconductor module. The first power terminal on the power semiconductor module may be formed to be planar.

The advantages of such a configuration of the power semiconductor module and the circuit arrangement as well as a corresponding procedure have already been pointed out. Both the power semiconductor module and the circuit arrangement and the method for their production can be refined in accordance with the statements in the context of this description, so that reference is made to these statements in this respect.

In one embodiment, the present disclosure provides that the first power terminal and the second power terminal may be formed on a flat outer wall of the power semiconductor module. The flat outer wall may be part of a housing of the power semiconductor module.

In one embodiment, the first power terminal and the second power terminal may be arranged on the same outer wall of the power semiconductor module. The outer wall is, for example, the top side of the power semiconductor module. On its bottom side opposite the top side, the power semiconductor module is configured to be attached to the heat sink.

In one embodiment, the first power terminal and the second power terminal may be arranged on opposite sides of the same outer wall. The first power terminal may be arranged in such a way that after the power semiconductor module has been attached to the heat sink, it is on a side of the outer wall facing the intermediate circuit capacitor. The second power terminal may be arranged in such a way that it is on a side of the outer wall facing away from the intermediate circuit capacitor. This enables an efficient connection of the power semiconductor module to the intermediate circuit capacitor, since a distance between the first power terminal and the intermediate circuit capacitor is minimized.

Additionally or alternatively, the first power terminal protrudes at least in sections beyond the outer wall on the side facing the intermediate circuit capacitor. This facilitates the connection of the first power terminal to the busbar of the intermediate circuit capacitor.

In one embodiment, the present disclosure provides that the first power terminal may be recessed in a recess of the flat outer wall. The first power terminal is formed to be planar on the flat outer wall, such as on the top side, of the power semiconductor module. The outer wall is provided with the recess in which the first power terminal is recessed.

The recess extends through the outer wall and is open at the side. The recess is configured in such a way that the busbar of the intermediate circuit capacitor can be brought into engagement with it at least in sections, with the busbar being in touching contact with the first power terminal. A depth of the recess perpendicular to the outer wall may be dimensioned in such a way that the busbar does not protrude beyond the outer wall in a direction perpendicular to the outer wall after being connected to the first power terminal. This creates a compact arrangement.

In one embodiment, the present disclosure provides that at least one further contact pin which is connected to a control terminal of the power semiconductor may be present on the flat outer wall. The control terminal is used to control the power semiconductor which is arranged in the power semiconductor module. The contact pin projects beyond the power semiconductor module.

The control terminal or the contact pin connected to the control terminal is arranged between the first power terminal and the second power terminal on the flat outer wall. The control board has a further contact recess into which the contact pin of the control terminal is pressed when the control board is connected to the power semiconductor module. This enables a compact configuration of the control board.

The present disclosure further relates to a circuit arrangement for an electric machine, such as a circuit arrangement according to the statements in the context of this description, wherein the circuit arrangement has at least one power input which is connectable to an electric energy storage device, at least one power semiconductor which is arranged in a power semiconductor module, and at least one power output which is connectable to an excitation coil of the electric machine, wherein the power input is electrically connected to a first power terminal of the power semiconductor module via an intermediate circuit of the circuit arrangement, and the power output is electrically connected to a second power terminal of the power semiconductor module via a control board of the circuit arrangement, wherein the second power terminal is formed as at least one contact pin that protrudes beyond the power semiconductor module and is pressed into a contact recess in the control board. In this case, the first power terminal on the power semiconductor module may be formed to be planar and is electrically and mechanically connected to a busbar of an intermediate circuit capacitor of the intermediate circuit.

The advantages of such a configuration of the circuit arrangement as well as a corresponding power semiconductor module have already been pointed out. Both the circuit arrangement and the power semiconductor module can be refined in accordance with the statements in the context of this description, so reference is made to these statements in this respect.

The features and combinations of features described in the description, such as the features and combinations of features described in the following description of the figures and/or shown in the figures, can be used not only in the combination specified in each case, but also in other combinations or on their own, without departing from the scope of the present disclosure. Embodiments are also to be regarded as being encompassed by the present disclosure that are not explicitly shown or explained in the description and/or in the figures, but which emerge from the explained embodiments through combinations of features or can be derived therefrom.

### BRIEF DESCRIPTION OF THE SEVERAL VIEWS OF THE DRAWINGS

The present disclosure is explained in more detail below with reference to the embodiments shown in the drawing.

FIG. 1 shows a schematic representation of a power semiconductor module for a circuit arrangement for an electric machine.

FIG. 2 shows a schematic representation of a circuit arrangement for an electric machine.

### DETAILED DESCRIPTION

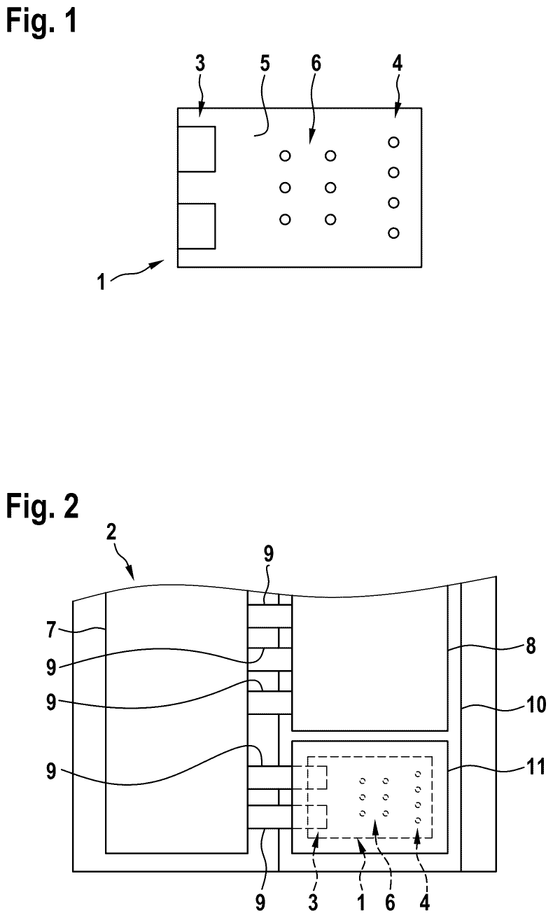

FIG. 1 shows a power semiconductor module 1 for a circuit arrangement 2 of an electric machine, not illustrated in detail. The power semiconductor module 1 has a first power terminal 3 and a second power terminal 4, which are electrically connected to one another via a power semiconductor, not illustrated in detail. The power semiconductor module 1 may be in the form of a DC-DC converter, by which an input voltage present at the first power terminal 3 is converted into an output voltage present at the second power terminal 4.

The first power terminal 3 and the second power terminal 4 are formed on a flat outer wall 5 of the power semiconductor module 1. The first power terminal 3 is formed to be planar on the power semiconductor module 1. In the example illustrated, the first power terminal 3 has two contact surfaces which are arranged at a distance from one another, between which the input voltage is applied.

The second power terminal 4 is present as several contact pins protruding beyond the power semiconductor module 1. In the example illustrated, the second power terminal 4 has four contact pins, with the output voltage being present between two of the four contact pins.

The two power terminals 3, 4 are arranged on opposite sides of an outer wall 5. Between the power terminals 3, 4, a control terminal 6 is provided, which is present as several contact pins protruding beyond the power semiconductor module 1. The control terminal 6 serves to control the power semiconductor which is arranged in the power semiconductor module 1. In the example illustrated, the control terminal 6 has a total of six contact pins.

FIG. 2 shows a circuit arrangement 2 for the electric machine not illustrated in detail. The circuit arrangement 2 comprises the power semiconductor module 1, an intermediate circuit capacitor 7, as well as an inverter 8. A power input, not illustrated in detail, of the circuit arrangement 2 is connectable to an electric energy storage device.

The power input is connected to the intermediate circuit capacitor 7, which has several busbars 9 for connection to the power semiconductor module 1 and the inverter 8. The circuit arrangement 2 comprises several inverters 8, with only one inverter 8 being illustrated here. The intermediate circuit capacitor 7 provides an intermediate circuit voltage via busbars 9, which serves as an input voltage of the power semiconductor module 1 and the inverter 8. For example, the intermediate circuit capacitor 7 has at least two busbars 9, each of which is connected to a pole of the intermediate circuit capacitor 7.

The power semiconductor module 1 is attached to a heat sink 10 of the circuit arrangement 1 via a bottom side of the power semiconductor module 1. The power semiconductor module 1 is connected to a control board 11 via a top side of the power semiconductor module 1. The power semiconductor module 1 is covered by the control board 11, which is why the power semiconductor module 1 is illustrated in dashed lines.

The contact pins of the second power terminal 4 as well as the contact pins of the control terminal 6 of the power semiconductor module 1 are electrically and mechanically connected to the control board 11 by being pressed into corresponding contact recesses in the control board 11.

The first power terminal 3 of the power semiconductor module 1, however, is electrically and mechanically connected to busbars 9 of the intermediate circuit capacitor 7 bypassing the control board 11. The busbars 9 engage in a recess present on the outer wall 5 of the power semiconductor module 1, in which the connection surfaces of the first power terminal 3 are recessed.

The control board 11 connectable to an excitation coil of the electric machine via a power output, not illustrated in detail, of circuit arrangement 1. By the power semiconductor module 2, an excitation voltage for an excitation coil of the electric machine is provided from the intermediate circuit voltage present at the first power terminal 3 at the power output.

To produce the circuit arrangement 2, the power semiconductor module 1 is first attached with its bottom side to heat sink 10. This is done by surface sintering and/or surface soldering.

After the power semiconductor module 1 has been attached to the heat sink 10, the busbars 9 of the intermediate circuit capacitor 7 are electrically and mechanically connected to the contact surfaces of the first power terminal 3 of the power semiconductor module 1 by welding.

The control board 11 is then connected to the power semiconductor module 1 by pressing in the contact pins of the second power terminal 4 as well as control terminals 6.

Alternatively, after the power semiconductor module 1 has been attached to the heat sink, it is provided that the control board is first connected to the power semiconductor module 1 by pressing in the contact pins. The first power terminal 3 of the power semiconductor module 1 is then electrically and mechanically connected to the busbars 9 of the intermediate circuit capacitor 7.

German patent application no. 10 2023 126 438.9 filed Sep. 28, 2023, to which this application claims priority, is hereby incorporated herein by reference, in its entirety.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A method for producing a circuit arrangement for an electric machine, wherein the circuit arrangement has at least one power input which is connectable to an electric energy storage device, at least one power semiconductor which is arranged in a power semiconductor module, and at least one power output which is connectable to an excitation coil of the electric machine, the method comprising:
electrically connecting the power input to a first power terminal of the power semiconductor module via an intermediate circuit of the circuit arrangement;
electrically connecting the power output to a second power terminal of the power semiconductor module via a control board of the circuit arrangement, wherein the second power terminal is formed as at least one contact pin that protrudes beyond the power semiconductor module and is pressed into a contact recess in the control board, wherein the first power terminal on the power semiconductor module is formed to be planar and is electrically and mechanically connected to a busbar of an intermediate circuit capacitor of the intermediate circuit.

2. The method according to claim 1, wherein the power semiconductor module is attached to a heat sink of the circuit arrangement before connecting the first power terminal to the busbar of the intermediate circuit capacitor.

3. The method according to claim 1, wherein the power semiconductor module is attached to the heat sink by surface sintering and/or surface soldering.

4. The method according to claim 1, wherein the first power terminal is electrically and mechanically connected to the busbar of the intermediate circuit capacitor by welding.

5. The method according to claim 1, wherein the control board is connected to the power semiconductor module by pressing the at least one contact pin into the contact recess of the control board after attaching the power semiconductor module to the heat sink.

6. A power semiconductor module, comprising:
a circuit arrangement for an electric machine, produced by a method comprising electrically connecting a power input to a first power terminal of the power semiconductor module via an intermediate circuit of the circuit arrangement, and electrically connecting a power output to a second power terminal of the power semiconductor module via a control board of the circuit arrangement, wherein the second power terminal is formed as at least one contact pin that protrudes beyond the power semiconductor module and is pressed into a contact recess in the control board, wherein the first power terminal on the power semiconductor module is formed to be planar and is electrically and mechanically connected to a busbar of an intermediate circuit capacitor of the intermediate circuit,
wherein the power semiconductor module has the first power terminal and the second power terminal which are electrically connected to one another via a power semiconductor arranged in the power semiconductor module,
wherein the second power terminal is formed as the at least one contact pin protruding beyond the power semiconductor module, and
wherein the first power terminal on the power semiconductor is formed to be planar.

7. The power semiconductor module according to claim 6, wherein the first power terminal is formed on a flat outer wall of the power semiconductor module.

8. The power semiconductor module according to claim 6, wherein the first power terminal is recessed in a recess of the flat outer wall.

9. The power semiconductor module according to claim 6, wherein at least one further contact pin connected to a control terminal of the power semiconductor is present on the flat outer wall.

10. A circuit arrangement for an electric machine with a power semiconductor module according to claim 6, wherein the circuit arrangement has at least one power input which is connectable to an electric energy storage device, at least one power semiconductor which is arranged in a power semiconductor module, and at least one power output which is connectable to an excitation coil of the electric machine, wherein the power input is electrically connected to a first power terminal of the power semiconductor module via an intermediate circuit of the circuit arrangement, and the power output is electrically connected to a second power terminal of the power semiconductor module via a control board of the circuit arrangement, wherein the second power terminal is formed as at least one contact pin that protrudes beyond the power semiconductor module and is pressed into a contact recess in the control board, and wherein the first power terminal on the power semiconductor module is formed to be planar and is electrically and mechanically connected to a busbar of an intermediate circuit capacitor of the intermediate circuit.
